(19) United States
(12) Patent Application Publication
(10) Pub. No.: US 2018/0323860 A1
(43) Pub. Date: Nov. 8, 2018

(54) SIGNAL BOOSTER SYSTEM WITH AUTOMATIC GAIN CONTROL

(71) Applicant: WILSON ELECTRONICS, LLC, St. George, UT (US)

(72) Inventors: DOUGLAS EDWARD BOHLS, Allen, TX (US); WILLIAM IRL THORNTON, Plano, TX (US); DALE ROBERT ANDERSON, Colleyville, TX (US); GLEN RAGGIO, Mesquite, TX (US); CHRISTOPHER KEN ASHWORTH, St. George, UT (US)

(21) Appl. No.: 15/974,492

(22) Filed: May 8, 2018

Related U.S. Application Data
(60) Provisional application No. 62/503,227, filed on May 8, 2017.

(51) Int. Cl. H04B 7/155; H03G 3/30; G05B 13/02

(52) U.S. Cl. CPC H04B 7/15535; H03G 3/3042; H04W 52/52; H03G 3/3052; G05B 13/0205

(57) ABSTRACT

Technology for a signal booster system is disclosed. The signal booster system can include a main signal booster and a plurality of inline signal boosters. The plurality of inline signal boosters can be communicatively coupled to the main signal booster via separate coaxial cables. Each inline signal booster in the plurality of inline signal boosters can be configured to set its uplink automatic gain control (AGC) based on dynamic gain information received from the main signal booster.

### RELATED APPLICATIONS

The present application claims the benefit of U.S. Provisional Patent Application No. 62/503,227, filed May 8, 2017 with a docket number of 3969-132.PROV, the entire specification of which is hereby incorporated by reference in its entirety for all purposes.

### BACKGROUND

Signal boosters and repeaters can be used to increase the quality of wireless communication between a wireless device and a wireless communication access point, such as a cell tower. Signal boosters can improve the quality of the wireless communication by amplifying, filtering, and/or applying other processing techniques to uplink and downlink signals communicated between the wireless device and the wireless communication access point.

As an example, the signal booster can receive, via an antenna, downlink signals from the wireless communication access point. The signal booster can amplify the downlink signal and then provide an amplified downlink signal to the wireless device. In other words, the signal booster can act as a relay between the wireless device and the wireless communication access point. As a result, the wireless device can receive a stronger signal from the wireless communication access point. Similarly, uplink signals from the wireless device (e.g., telephone calls and other data) can be directed to the signal booster. The signal booster can amplify the uplink signals before communicating, via an antenna, the uplink signals to the wireless communication access point.

### BRIEF DESCRIPTION OF THE DRAWINGS

Features and advantages of the disclosure will be apparent from the detailed description which follows, taken in conjunction with the accompanying drawings, which together illustrate, by way of example, features of the disclosure; and, wherein:

FIG. 1 illustrates a signal booster in communication with a wireless device and a base station in accordance with an example;

FIG. 2 illustrates a cellular signal booster configured to amplify uplink (UL) and downlink (DL) signals using one or more downlink signal paths and one or more uplink signal paths in accordance with an example;

FIG. 3 illustrates a main signal booster communicatively coupled to an inline signal booster in accordance with an example;

FIG. 4 illustrates a main signal booster communicatively coupled to a plurality of inline signal boosters in parallel in accordance with an example;

FIG. 5 illustrates a main signal booster communicatively coupled to a plurality of inline signal boosters in series in accordance with an example; and

FIG. 6 illustrates a wireless device in accordance with an example.

Reference will now be made to the exemplary embodiments illustrated, and specific language will be used herein to describe the same. It will nevertheless be understood that no limitation of the scope of the invention is thereby intended.

### DETAILED DESCRIPTION

Before the present invention is disclosed and described, it is to be understood that this invention is not limited to the particular structures, process steps, or materials disclosed herein, but is extended to equivalents thereof as would be recognized by those ordinarily skilled in the relevant arts. It should also be understood that terminology employed herein is used for the purpose of describing particular examples only and is not intended to be limiting. The same reference numerals in different drawings represent the same element. Numbers provided in flow charts and processes are provided for clarity in illustrating steps and operations and do not necessarily indicate a particular order or sequence.

### Example Embodiments

An initial overview of technology embodiments is provided below and then specific technology embodiments are described in further detail later. This initial summary is intended to aid readers in understanding the technology more quickly but is not intended to identify key features or essential features of the technology nor is it intended to limit the scope of the claimed subject matter.

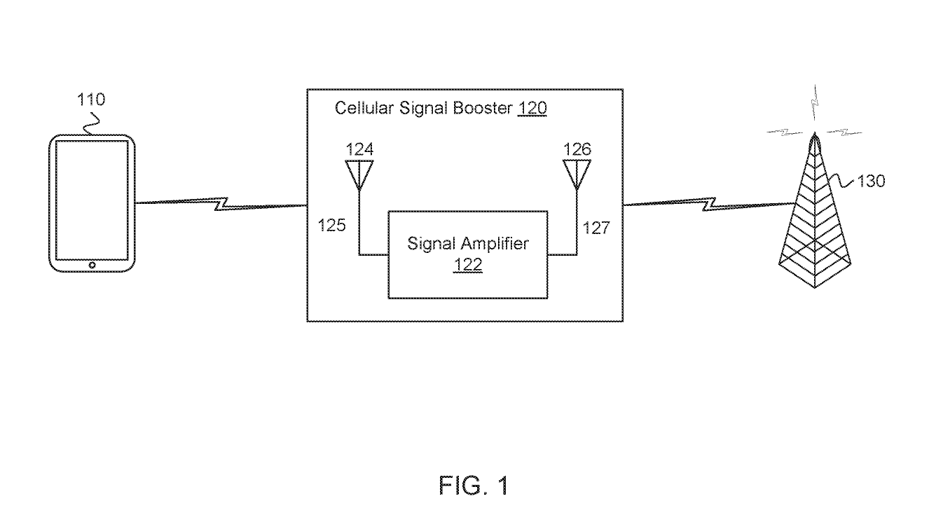

FIG. 1 illustrates an exemplary signal booster 120 in communication with a wireless device 110 and a base station 130. The signal booster 120 can be referred to as a repeater. A repeater can be an electronic device used to amplify (or boost) signals. The signal booster 120 (also referred to as a cellular signal amplifier) can improve the quality of wireless communication by amplifying, filtering, and/or applying other processing techniques via a signal amplifier 122 to uplink signals communicated from the wireless device 110 to the base station 130 and/or downlink signals communicated from the base station 130 to the wireless device 110. In other words, the signal booster 120 can amplify or boost uplink signals and/or downlink signals bi-directionally. In one example, the signal booster 120 can be at a fixed location, such as in a home or office. Alternatively, the signal booster 120 can be attached to a mobile object, such as a vehicle or a wireless device 110.

In one configuration, the signal booster 120 can include an integrated device antenna 124 (e.g., an inside antenna or a coupling antenna) and an integrated node antenna 126 (e.g., an outside antenna). The integrated node antenna 126 can receive the downlink signal from the base station 130. The downlink signal can be provided to the signal amplifier 122 via a second coaxial cable 127 or other type of radio frequency connection operable to communicate radio frequency signals. The signal amplifier 122 can include one or more cellular signal amplifiers for amplification and filtering. The downlink signal that has been amplified and filtered can be provided to the integrated device antenna 124 via a first coaxial cable 125 or other type of radio frequency connection operable to communicate radio frequency signals. The integrated device antenna 124 can wirelessly communicate the downlink signal that has been amplified and filtered to the wireless device 110.

Similarly, the integrated device antenna 124 can receive an uplink signal from the wireless device 110. The uplink signal can be provided to the signal amplifier 122 via the first coaxial cable 125 or other type of radio frequency connection operable to communicate radio frequency signals. The signal amplifier 122 can include one or more cellular signal amplifiers for amplification and filtering. The uplink signal that has been amplified and filtered can be provided to the integrated node antenna 126 via the second coaxial cable 127 or other type of radio frequency connection operable to communicate radio frequency signals. The integrated device antenna 126 can communicate the uplink signal that has been amplified and filtered to the base station 130.

In one example, the signal booster 120 can filter the uplink and downlink signals using any suitable analog or digital filtering technology including, but not limited to, surface acoustic wave (SAW) filters, bulk acoustic wave (BAW) filters, film bulk acoustic resonator (FBAR) filters, ceramic filters, waveguide filters or low-temperature co-fired ceramic (LTCC) filters.

In one example, the signal booster 120 can send uplink signals to a node and/or receive downlink signals from the node. The node can comprise a wireless wide area network (WWAN) access point (AP), a base station (BS), an evolved Node B (eNB), a baseband unit (BBU), a remote radio head (RRH), a remote radio equipment (RRE), a relay station (RS), a radio equipment (RE), a remote radio unit (RRU), a central processing module (CPM), or another type of WWAN access point.

In one configuration, the signal booster 120 used to amplify the uplink and/or a downlink signal is a handheld booster. The handheld booster can be implemented in a sleeve of the wireless device 110. The wireless device sleeve can be attached to the wireless device 110, but can be removed as needed. In this configuration, the signal booster 120 can automatically power down or cease amplification when the wireless device 110 approaches a particular base station. In other words, the signal booster 120 can determine to stop performing signal amplification when the quality of uplink and/or downlink signals is above a defined threshold based on a location of the wireless device 110 in relation to the base station 130.

In one example, the signal booster 120 can include a battery to provide power to various components, such as the signal amplifier 122, the integrated device antenna 124 and the integrated node antenna 126. The battery can also power the wireless device 110 (e.g., phone or tablet). Alternatively, the signal booster 120 can receive power from the wireless device 110.

In one configuration, the signal booster 120 can be a Federal Communications Commission (FCC)-compatible consumer signal booster. As a non-limiting example, the signal booster 120 can be compatible with FCC Part 20 or 47 Code of Federal Regulations (C.F.R.) Part 20.21 (Mar. 21, 2013). In addition, the signal booster 120 can operate on the frequencies used for the provision of subscriber-based services under parts 22 (Cellular), 24 (Broadband PCS), 27 (AWS-1, 700 MHz Lower A-E Blocks, and 700 MHz Upper C Block), and 90 (Specialized Mobile Radio) of 47 C.F.R. The signal booster 120 can be configured to automatically self-monitor its operation to ensure compliance with applicable noise and gain limits. The signal booster 120 can either self-correct or shut down automatically if the signal booster's operations violate the regulations defined in FCC Part 20.21.

In one configuration, the signal booster 120 can improve the wireless connection between the wireless device 110 and the base station 130 (e.g., cell tower) or another type of wireless wide area network (WWAN) access point (AP). The signal booster 120 can boost signals for cellular standards, such as the Third Generation Partnership Project (3GPP) Long Term Evolution (LTE) Release 8, 9, 10, 11, 12, or 13 standards or Institute of Electronics and Electrical Engineers (IEEE) 802.16. In one configuration, the signal booster 120 can boost signals for 3GPP LTE Release 13.0.0 (March 2016) or other desired releases. The signal booster 120 can boost signals from the 3GPP Technical Specification 36.101 (Release 12 June 2015) bands or LTE frequency bands. For example, the signal booster 120 can boost signals from the LTE frequency bands: 2, 4, 5, 12, 13, 17, and 25. In addition, the signal booster 120 can boost selected frequency bands based on the country or region in which the signal booster is used, including any of bands 1-70 or other bands, as disclosed in ETSI TS136 104 V13.5.0 (2016-10).

The number of LTE frequency bands and the level of signal improvement can vary based on a particular wireless device, cellular node, or location. Additional domestic and international frequencies can also be included to offer increased functionality. Selected models of the signal booster 120 can be configured to operate with selected frequency bands based on the location of use. In another example, the signal booster 120 can automatically sense from the wireless device 110 or base station 130 (or GPS, etc.) which frequencies are used, which can be a benefit for international travelers.

In one example, the integrated device antenna 124 and the integrated node antenna 126 can be comprised of a single antenna, an antenna array, or have a telescoping form-factor. In another example, the integrated device antenna 124 and the integrated node antenna 126 can be a microchip antenna. An example of a microchip antenna is AMMAL001. In yet another example, the integrated device antenna 124 and the integrated node antenna 126 can be a printed circuit board (PCB) antenna. An example of a PCB antenna is TE 2118310-1.

In one example, the integrated device antenna 124 can receive uplink (UL) signals from the wireless device 100 and transmit DL signals to the wireless device 100 using a single antenna. Alternatively, the integrated device antenna 124 can receive UL signals from the wireless device 100 using a dedicated UL antenna, and the integrated device antenna 124 can transmit DL signals to the wireless device 100 using a dedicated DL antenna.

In one example, the integrated device antenna 124 can communicate with the wireless device 110 using near field communication. Alternatively, the integrated device antenna 124 can communicate with the wireless device 110 using far field communication.

In one example, the integrated node antenna 126 can receive downlink (DL) signals from the base station 130 and transmit uplink (UL) signals to the base station 130 via a single antenna. Alternatively, the integrated node antenna 126 can receive DL signals from the base station 130 using a dedicated DL antenna, and the integrated node antenna 126 can transmit UL signals to the base station 130 using a dedicated UL antenna.

In one configuration, multiple signal boosters can be used to amplify UL and DL signals. For example, a first signal booster can be used to amplify UL signals and a second signal booster can be used to amplify DL signals. In addition, different signal boosters can be used to amplify different frequency ranges.

In one configuration, the signal booster 120 can be configured to identify when the wireless device 110 receives a relatively strong downlink signal. An example of a strong downlink signal can be a downlink signal with a signal strength greater than approximately −80 dBm. The signal booster 120 can be configured to automatically turn off selected features, such as amplification, to conserve battery life. When the signal booster 120 senses that the wireless device 110 is receiving a relatively weak downlink signal, the integrated booster can be configured to provide amplification of the downlink signal. An example of a weak downlink signal can be a downlink signal with a signal strength less than −80 dBm.

In one example, the signal booster 120 can also include one or more of: a waterproof casing, a shock absorbent casing, a flip-cover, a wallet, or extra memory storage for the wireless device. In one example, extra memory storage can be achieved with a direct connection between the signal booster 120 and the wireless device 110. In another example, Near-Field Communications (NFC), Bluetooth v4.0, Bluetooth Low Energy, Bluetooth v4.1, Bluetooth v4.2, Bluetooth 5, Ultra High Frequency (UHF), 3GPP LTE, Institute of Electronics and Electrical Engineers (IEEE) 802.11a, IEEE 802.11b, IEEE 802.11g, IEEE 802.11n, IEEE 802.11ac, or IEEE 802.11ad can be used to couple the signal booster 120 with the wireless device 110 to enable data from the wireless device 110 to be communicated to and stored in the extra memory storage that is integrated in the signal booster 120. Alternatively, a connector can be used to connect the wireless device 110 to the extra memory storage.

In one example, the signal booster 120 can include photovoltaic cells or solar panels as a technique of charging the integrated battery and/or a battery of the wireless device 110. In another example, the signal booster 120 can be configured to communicate directly with other wireless devices with signal boosters. In one example, the integrated node antenna 126 can communicate over Very High Frequency (VHF) communications directly with integrated node antennas of other signal boosters. The signal booster 120 can be configured to communicate with the wireless device 110 through a direct connection, Near-Field Communications (NFC), Bluetooth v4.0, Bluetooth Low Energy, Bluetooth v4.1, Bluetooth v4.2, Ultra High Frequency (UHF), 3GPP LTE, Institute of Electronics and Electrical Engineers (IEEE) 802.11a, IEEE 802.11b, IEEE 802.11g, IEEE 802.11n, IEEE 802.11ac, IEEE 802.11ad, a TV White Space Band (TVWS), or any other industrial, scientific and medical (ISM) radio band. Examples of such ISM bands include 2.4 GHz, 3.6 GHz, 4.9 GHz, 5 GHz, or 5.9 GHz. This configuration can allow data to pass at high rates between multiple wireless devices with signal boosters. This configuration can also allow users to send text messages, initiate phone calls, and engage in video communications between wireless devices with signal boosters. In one example, the integrated node antenna 126 can be configured to couple to the wireless device 110. In other words, communications between the integrated node antenna 126 and the wireless device 110 can bypass the integrated booster.

In another example, a separate VHF node antenna can be configured to communicate over VHF communications directly with separate VHF node antennas of other signal boosters. This configuration can allow the integrated node antenna 126 to be used for simultaneous cellular communications. The separate VHF node antenna can be configured to communicate with the wireless device 110 through a direct connection, Near-Field Communications (NFC), Bluetooth v4.0, Bluetooth Low Energy, Bluetooth v4.1, Bluetooth v4.2, Ultra High Frequency (UHF), 3GPP LTE, Institute of Electronics and Electrical Engineers (IEEE) 802.11a, IEEE 802.11b, IEEE 802.11g, IEEE 802.11n, IEEE 802.11ac, IEEE 802.11ad, a TV White Space Band (TVWS), or any other industrial, scientific and medical (ISM) radio band.

In one configuration, the signal booster 120 can be configured for satellite communication. In one example, the integrated node antenna 126 can be configured to act as a satellite communication antenna. In another example, a separate node antenna can be used for satellite communications. The signal booster 120 can extend the range of coverage of the wireless device 110 configured for satellite communication. The integrated node antenna 126 can receive downlink signals from satellite communications for the wireless device 110. The signal booster 120 can filter and amplify the downlink signals from the satellite communication. In another example, during satellite communications, the wireless device 110 can be configured to couple to the signal booster 120 via a direct connection or an ISM radio band. Examples of such ISM bands include 2.4 GHz, 3.6 GHz, 4.9 GHz, 5 GHz, or 5.9 GHz.

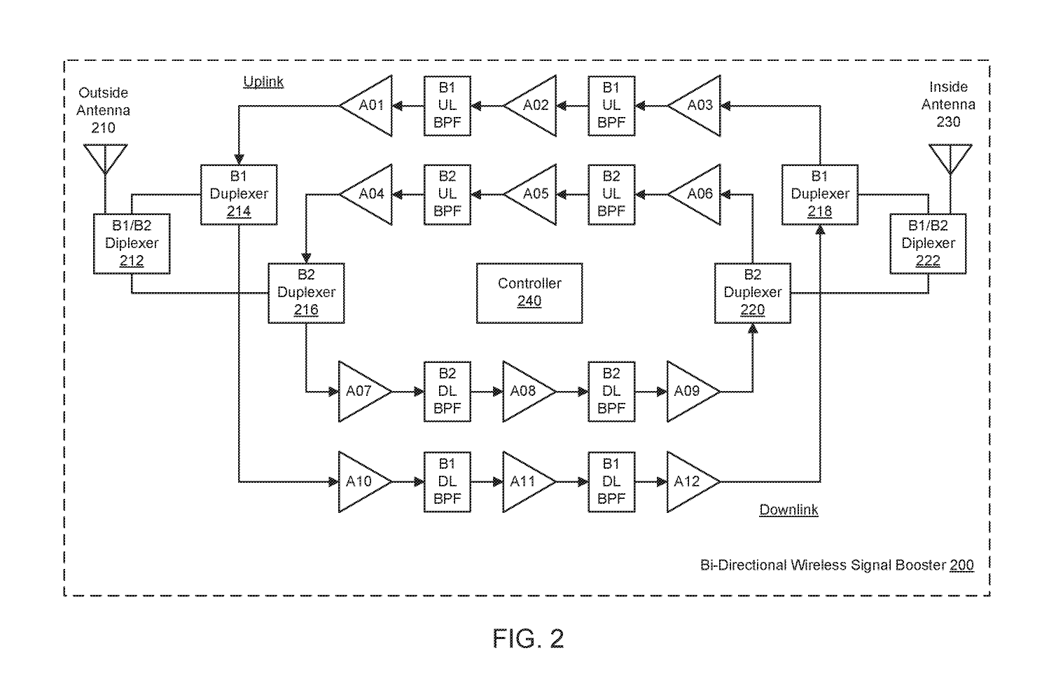

FIG. 2 illustrates an exemplary bi-directional wireless signal booster 200 configured to amplify uplink (UL) and downlink (DL) signals using a separate signal path for each UL frequency band and DL frequency band and a controller 240. An outside antenna 210, or an integrated node antenna, can receive a downlink signal. For example, the downlink signal can be received from a base station (not shown). The downlink signal can be provided to a first B1/B2 diplexer 212, wherein B1 represents a first frequency band and B2 represents a second frequency band. The first B1/B2 diplexer 212 can create a B1 downlink signal path and a B2 downlink signal path. Therefore, a downlink signal that is associated with B1 can travel along the B1 downlink signal path to a first B1 duplexer 214, or a downlink signal that is associated with B2 can travel along the B2 downlink signal path to a first B2 duplexer 216. After passing the first B1 duplexer 214, the downlink signal can travel through a series of amplifiers (e.g., A10, A11 and A12) and downlink band pass filters (BPF) to a second B1 duplexer 218. Alternatively, after passing the first B2 duplexer 216, the downlink can travel through a series of amplifiers (e.g., A07, A08 and A09) and downlink band pass filters (BFF) to a second B2 duplexer 220. At this point, the downlink signal (B1 or B2) has been amplified and filtered in accordance with the type of amplifiers and BPFs included in the bi-directional wireless signal booster 200. The downlink signals from the second B1 duplexer 218 or the second B2 duplexer 220, respectively, can be provided to a second B1/B2 diplexer 222. The second B1/B2 diplexer 222 can provide an amplified downlink signal to an inside antenna 230, or an integrated device antenna. The inside antenna 230 can communicate the amplified downlink signal to a wireless device (not shown), such as a mobile phone.

In one example, the inside antenna 230 can receive an uplink (UL) signal from the wireless device. The uplink signal can be provided to the second B1/B2 diplexer 222. The second B1/B2 diplexer 222 can create a B1 uplink signal path and a B2 uplink signal path. Therefore, an uplink signal that is associated with B1 can travel along the B1 uplink signal path to the second B1 duplexer 218, or an uplink signal that is associated with B2 can travel along the B2 uplink signal path to the second B2 duplexer 222. After passing the second B1 duplexer 218, the uplink signal can travel through a series of amplifiers (e.g., A01, A02 and A03) and uplink band pass filters (BPF) to the first B1 duplexer 214. Alternatively, after passing the second B2 duplexer 220, the uplink signal can travel through a series of amplifiers (e.g., A04, A05 and A06) and uplink band pass filters (BPF) to the first B2 duplexer 216. At this point, the uplink signal (B1 or B2) has been amplified and filtered in accordance with the type of amplifiers and BFFs included in the bi-directional wireless signal booster 200. The uplink signals from the first B1 duplexer 214 or the first B2 duplexer 216, respectively, can be provided to the first B1/B2 diplexer 212. The first B1/B2 diplexer 212 can provide an amplified uplink signal to the outside antenna 210. The outside antenna can communicate the amplified uplink signal to the base station.

In one example, the bi-directional wireless signal booster 200 can be a 6-band booster. In other words, the bi-directional wireless signal booster 200 can perform amplification and filtering for downlink and uplink signals having a frequency in bands B1, B2, B3 B4, B5 and/or B6.

In one example, the bi-directional wireless signal booster 200 can use the duplexers to separate the uplink and downlink frequency bands, which are then amplified and filtered separately. A multiple-band cellular signal booster can typically have dedicated radio frequency (RF) amplifiers (gain blocks), RF detectors, variable RF attenuators and RF filters for each uplink and downlink band.

In one configuration, a signal booster system (or repeater system) can improve cellular service in a building. The signal booster system can be a cascaded inline booster system, which includes inline signal booster(s) (or inline repeaters) that are connected to a main signal booster (or main repeater) using a variable length coaxial cable. The main signal booster can communicate with the inline signal booster(s) over variable length coaxial cable(s). In one example, the inline signal booster can only function along with the main signal booster, or alternatively, the inline signal booster can function independent of the main signal booster. The main signal booster can be communicatively coupled to an outside antenna (or donor antenna) via an outside antenna port (or donor antenna port). The inline signal booster(s) can be connected in series or in parallel. For example, inline signal boosters(s) in parallel can each be connected to an inside antenna (or server antenna) via respective inside antenna ports (or server antenna ports), whereas inline signal booster(s) in series can be connected to a single inside antenna (or server antenna) via an inside antenna port (or server antenna port) on a last inline signal booster in the series. The inline signal booster(s) can augment a signal boosting capability of the main signal booster. In addition, the inline signal booster(s) can mitigate a coaxial cable loss, thereby providing an improved physical reach as compared to a conventional single booster system. In other words, a cascaded inline booster system with a main signal booster and multiple inline signal boosters that are spread throughout a building (connected via coaxial cables of variable lengths) can provide an improved signal boosting capability for the building as compared to the conventional single booster system.

In one example, the main signal booster in the signal booster system can include uplink automatic gain control (AGC) and downlink AGC. The uplink AGC can function to adjust an uplink gain or noise power and the downlink AGC can function to adjust a downlink gain or noise power. In one example, the uplink AGC in the main signal booster can adjust the uplink gain or noise power based on a signal strength (or power level) of a received downlink signal from a base station. For example, the uplink AGC in the main signal booster can adjust the uplink gain or noise power to meet a network protection standard. The AGC control functions in the main signal booster can maintain the network protection standards for uplink and downlink, as required in Part 20 of the FCC Consumer Booster Rules. In one example, the downlink AGC in the main signal booster can be a fixed gain block, whereas the uplink AGC in the main signal booster can be gain controlled.

The main signal booster in the signal booster system can include both uplink AGC and downlink AGC control functions, but may still suffer from a suboptimal uplink power/linearity performance when the signal booster system is gain-limited for a downlink AGC differential. Therefore, it can be advantageous for the inline signal booster in the signal booster system to also include uplink AGC, which can optimize power/linearity for the signal booster system. In this example, the main signal booster can include system downlink AGC control functions, while both the main signal booster and the inline signal booster can include inter-dependent system uplink AGC control functions, which can be configured to maintain network protection standards.

In one example, uplink AGC in the main signal booster can start before uplink AGC in the inline signal booster to maintain a system uplink output power at a level that meets system uplink intermodulation (IM) power limits. A further increase in a system uplink input power can be automatic gain controlled by the main signal booster to maintain network protection, but at some point, the system uplink input power into the main signal booster can exceed the main signal booster's ability to maintain the network protection with its own uplink AGC control. Therefore, the inline signal booster can start its own uplink AGC to level its uplink output power into the main signal booster to maintain an overall system IM performance. Therefore, both uplink AGCs (i.e., in the main signal booster and the inline signal booster) can be used to maximize system output power while optimizing a main signal booster uplink input power to achieve a maximum allowed gain and network linearity protection. In addition, since coaxial cable losses between the main signal booster and the inline signal boosters can make it more difficult to maintain IM power limits, it is important to have uplink AGC in the inline signal boosters as well as the main signal booster.

In one example, the main signal booster and the inline signal boosters can dynamically communicate with each other and cooperate to dynamically control a system gain to meet varying environmental and input signal conditions. In other words, the uplink AGC in the inline signal boosters can cooperatively function with the uplink AGC in the main signal booster. The inline signal boosters can receive dynamic communications from the main signal booster, and the inline signals boosters can appropriately set their respective uplink AGCs to optimize the signal booster system and maintain the network protection standard.

More specifically, the main signal booster can receive a downlink signal from a base station, and the main signal booster can receive uplink signals from the inline signal boosters. The main signal booster can measure a downlink received signal strength indicator (RSSI) based on the received downlink signal, as well as an uplink RSSI based on the received uplink signals. The main signal booster can adjust its uplink AGC based on the uplink RSSI of the received uplink signals and the downlink RSSI of the received downlink signal. The main signal booster can also adjust its downlink AGC based on the uplink RSSI and the downlink RSSI. In addition, the main signal booster can send dynamic gain information to the inline signal boosters included in the signal booster system. The dynamic gain information can include downlink RSSI information and uplink RSSI information. The dynamic gain information can be sent periodically (e.g., one per second). The inline signal boosters can receive the dynamic gain information from the main signal booster, and the inline signal boosters can adjust their respective uplink AGCs based on the dynamic gain information. The inline signal boosters can increase or decrease uplink gain based on the dynamic gain information. For example, based on the dynamic gain information, an inline signal booster can control a variable attenuator, which effectively changes an uplink gain for the inline signal booster. The inline signal boosters may have different uplink AGC capabilities. Therefore, a system gain for the signal booster system can be based on static system performance factors and dynamic input signal factors, such as the dynamic gain information with the downlink RSSI information and the uplink RSSI information. The uplink AGC control functions can be shared between the main signal booster and the inline signal boosters in the signal booster system. The inline signal boosters can adjust their respective uplink AGCs based on the downlink RSSI information using a lookup table, which can optimize gain or attenuation between system components to improve system linearity and transmit noise performance, as well as allow a non-linear response to system input changes (e.g., changes in the downlink RSSI).

In one example, a default distribution of system gain for the signal booster system (i.e., uplink AGC at the main signal booster versus uplink AGC at the inline signal boosters) can be determined during a field calibration. For example, the default distribution of system gain can depend on coaxial cable lengths (and corresponding coaxial cable losses) connecting the main signal booster to the inline signal boosters. The coaxial cable losses can be determined for each of the inline signal boosters during the field calibration. The default distribution of system gain can be a baseline for the main signal booster and the inline signal boosters under a low level signal input. The default distribution of system gain can be a static gain setting (as determined during the field calibration) for the main signal booster and the inline signal booster. In other words, the default distribution of system gain can be a static calibration setting (or baseline configuration setting) based on the coaxial cable lengths and corresponding coaxial cable losses. In one example, a first inline signal booster in the signal booster system can set its initial uplink gain setting differently than a second signal booster in the signal booster system based on a coaxial cable length (and corresponding coaxial cable loss) of the first inline signal booster versus the second inline signal booster. The default distribution of system gain can comply with overall system requirements set by the FCC.

After the field calibration, the signal booster system can start operating in a normal mode. At this point, the distribution of system gain for the signal booster system (i.e., uplink AGC at the main signal booster versus uplink AGC at the inline signal boosters) can be based on dynamic input signal factors, such as the dynamic gain information that includes the downlink RSSI information and the uplink RSSI information. As the dynamic gain information changes over a period of time, this dynamic distribution of system gain for the signal booster system can be modified. For example, based on the dynamic gain information, the main signal booster can adjust its uplink AGC accordingly and the inline signal boosters can adjust their respective uplink AGCs accordingly. In other words, the dynamic distribution of system gain is now based on a dynamic gain setting. The uplink AGCs of the main signal booster and the inline signal booster can work cooperatively to control an overall system uplink gain of the signal booster system. The overall system uplink gain can be in compliance with a requirement of a regulatory body for a cellular consumer or commercial signal booster system. In addition, the dynamic gain information can be communicated from the main signal booster to the inline signal booster in accordance with a timing that complies with a requirement of the regulatory body for the cellular consumer or commercial signal booster system.

In one example, uplink AGC set points for the inline signal boosters can be determined during the field calibration. The uplink AGC set points can be based on the coaxial cable lengths (and corresponding coaxial cable losses) connecting the main signal booster to the inline signal boosters. Therefore, different inline signal boosters can be associated with different uplink AGC set points. The uplink AGC set points can correspond to certain power levels. When an uplink AGC set point is met at a certain inline signal booster based on the dynamic gain information received from the main signal booster, the inline signal booster can adjust its uplink AGC to maintain network protection requirements. On the other hand, when the inline signal boosters receive dynamic gain information from the main signal booster that does not satisfy the uplink AGC set points, the inline signal boosters may not adjust their respective uplink AGCs.

In one configuration, the inline signal boosters can receive the dynamic gain information from the main signal booster, and then access the lookup table to determine an uplink AGC value to be applied at the inline signal boosters. The inline signal boosters can utilize the lookup table to portion an amount of uplink gain in one inline signal booster versus another amount of uplink gain at another inline signal booster. The lookup table can be shared between the inline signal boosters in the signal booster system. The different inline signal boosters can select uplink AGC values to adjust their uplink gain differently based on the lookup table. For example, based on the dynamic gain information (e.g., uplink RSSI information and downlink RSSI information), each inline signal boosters can select an appropriate uplink AGC value in view of their respective coaxial cable length (and corresponding coaxial cable loss). In other words, the lookup table can include uplink AGC values for each of the inline signal boosters that account for the coaxial cable lengths (and corresponding coaxial cable losses) for each of the inline signal boosters.

In one example, the lookup table can include fixed uplink AGC values that are designed to meet various FCC requirements for the signal booster system, such as noise power, output power, gain, etc. The fixed uplink AGC values can also be fixed to optimize an overall performance of the signal booster system. The possible uplink AGC values included in the lookup table for each of the inline signal boosters can be predetermined empirically in view of the FCC requirements and overall performance criteria. In one example, the lookup table can be a two-dimensional table. Based on the dynamic gain information (e.g., uplink RSSI information and downlink RSSI information) and for a specific inline signal booster, the lookup table can provide a corresponding uplink AGC value for the specific inline signal booster. For example, for a specific downlink RSSI/uplink RSSI and for a specific inline signal booster with a known coaxial cable loss, the lookup table can provide a particular uplink AGC value that is to be applied for that specific inline signal booster. When the main signal booster and each of the inline signal boosters set their uplink AGC value accordingly (i.e., based on the lookup table), an uplink system gain of the signal booster system can be in compliance with the FCC specification. The signal booster system, as a whole, can be considered as a typical single FCC approved signal booster. In addition, the lookup table can optimize gain or attenuation between system components (i.e., the main signal booster and the different inline signal boosters to improve system linearity and transmit noise performance, and the lookup table can allow a non-linear response to system input changes (e.g., inline signal boosters can each adjust their respective uplink gains differently as compared to the main signal booster).

In one example, the FCC can set a maximum power level requirement for the main signal booster, but a certain amount of loss can occur through the coaxial cable. Thus, the inline signal booster can serve to compensate for this loss, such that the signal booster system reverts back to the FCC maximum power level requirement. In some cases, the main signal booster might be capable of outputting additional power, but may be limited by the FCC maximum power level requirement. Since the inline signal booster can provide an additional uplink gain (which can be more than the coaxial cable loss), the main signal booster can be designed for a reduced amount of uplink gain and power. In one example, the main signal booster can be outputting a highest uplink gain as allowed by the FCC, and the inline signal boosters can merely be compensating for the coaxial cable loss. Alternatively, the main signal booster can provide a reduced uplink gain (e.g., 5 or 10 dB less than a maximum), and the inline signal boosters can provide an uplink gain that compensates for the coaxial cable losses plus the 5 or 10 dB. Different implementations can have different levels of uplink gain on the main signal booster versus the inline signal boosters. In another example, the inline signal boosters can output an uplink gain or power that is slightly greater than that of the main signal booster.

In one configuration, the main signal booster and/or the inline signal boosters can include multiple signal paths (i.e., channels) corresponding to different bands. For example, there can be multiple uplink channels, and each channel can be associated with a separate lookup table. Therefore, each lookup table can be independent of other lookup tables on different channelized signal paths. In addition, for a single channelization uplink path, there can be one uplink AGC in the main signal booster and one uplink AGC in the inline signal booster.

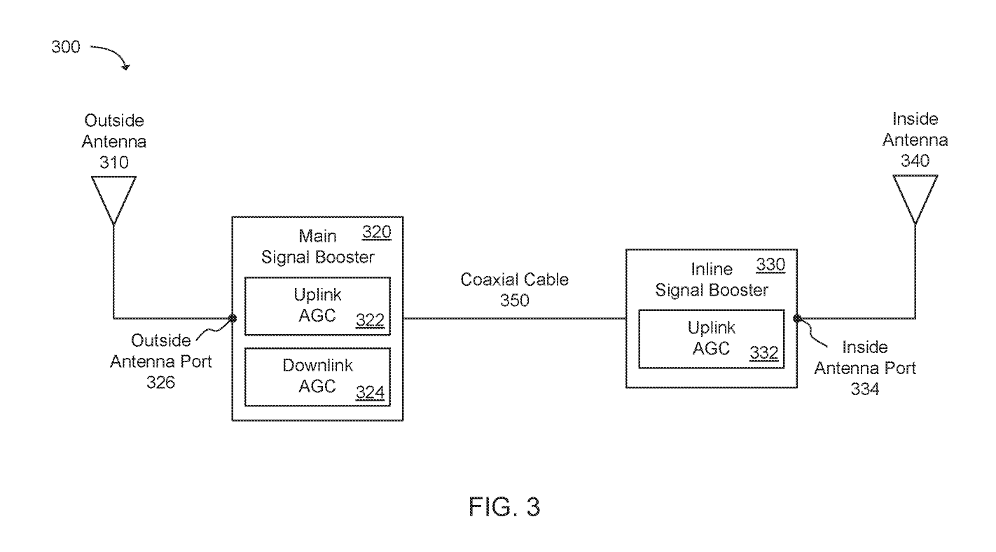

FIG. 3 illustrates an exemplary signal booster system 300 (or repeater system) that includes a main signal booster 320 (or main repeater) that is communicatively coupled to an inline signal booster 330 (or inline repeater). The inline signal booster 330 can also be referred to as a secondary signal booster (or secondary repeater). The main signal booster 320 and the inline signal booster 330 can be communicatively coupled via a coaxial cable 350. The main signal booster 320 and the inline signal booster 330 can both function to filter and amplify uplink and downlink signals. As described in further detail below, the main signal booster 320 and the inline signal booster 330 can cooperate to dynamically control a system gain of the signal booster system 300 to meet varying environmental and input signal conditions.

In one example, the main signal repeater 320 can be communicatively coupled to an outside antenna 310 (or donor antenna) via an outside antenna port 326 (or donor antenna port). The outside antenna 310 can be configured to transmit uplink signals to a base station (not shown) and receive downlink signals from the base station. In addition, the inline signal booster 330 can be communicatively coupled to an inside antenna 340 (or server antenna) via an inside antenna port 334 (or server antenna port). The inside antenna 340 can be configured to transmit downlink signals to a mobile device (not shown) and receive uplink signals from the mobile device.

In one example, the main signal booster 320 and the inline signal booster 330 can each include one or more downlink signal paths and one or more uplink signal paths. The downlink signal paths can include one or more amplifiers and one or more filters (e.g., analog filters) to amplify and filter downlink signals. Similarly, the uplink signal paths can include one or more amplifiers and one or more filters (e.g., analog filters) to amplify and filter uplink signals.

In one example, the main signal booster 320 can include an uplink automatic gain control (AGC) 322 and a downlink AGC 324. The uplink AGC 322 can be associated with one or more amplifiers for an uplink signal path of the main signal booster 320, and the downlink AGC 324 can be associated with one or more amplifiers for a downlink signal path of the main signal booster 320. The uplink AGC 322 can function to control an uplink gain of the uplink signal path in the main signal booster 320, and the downlink AGC 324 can function to control a downlink gain of the downlink signal path in the main signal booster 320. For example, the uplink AGC 322 can function to control the uplink gain of the uplink signal path in the main signal booster 320 order to meet network protection standards.

In one example, the inline signal booster 330 can include an uplink AGC 332. The uplink AGC 330 can be associated with one or more amplifiers for an uplink signal path of the inline signal booster 330. The uplink AGC 332 can function to control an uplink gain of the uplink signal path in the inline signal booster 332. For example, the uplink AGC 332 can function to control the uplink gain of the uplink signal path in the inline signal booster 330 in order to meet network protection standards.

In one configuration, the main signal booster 320 can receive a downlink signal from the base station via the outside antenna 310. The main signal booster 320 can receive an uplink signal from the inline signal booster 330. For example, the inline signal booster 330 can communicate uplink signals to the main signal booster 320 via the coaxial cable 350. The main signal booster 320 can determine dynamic gain information based on a power level associated with the downlink signal and/or a power level associated with the uplink signal. For example, the dynamic gain information can include downlink received signal strength indicator (RSSI) information and/or uplink RSSI information for the main signal booster 320.

In one example, the uplink AGC 322 in the main signal booster 320 can adjust an uplink gain or noise of the main signal booster 320 based on the dynamic gain information. In other words, the uplink AGC 322 in the main signal booster 320 can adjust an uplink gain or noise of the main signal booster 320 based on the downlink RSSI information and/or the uplink RSSI information. Thus, the main signal booster 320 can perform AGC (i.e., apply a dynamic uplink AGC setting) based on the dynamic gain information. In addition, the main signal booster 320 can send the dynamic gain information to the inline signal booster 330 over the coaxial cable 350. The main signal booster 320 can send the dynamic gain information at a periodic rate (e.g., once per second). In other words, in this example, the main signal booster 320 can send updated downlink and uplink RSSI information of the main signal booster 320 to the inline signal booster 330.

In one example, the inline signal booster 330 can receive the dynamic gain information from the main signal booster 320, and the uplink AGC 332 in the inline signal booster 330 can set an uplink gain or noise of the inline signal booster 330 based on the dynamic gain information (e.g., the downlink RSSI information and/or the uplink RSSI information). Thus, the inline signal booster 330 can perform uplink AGC (i.e., apply a dynamic uplink AGC setting) based on the dynamic gain information received from the main signal booster 320.

In one example, the inline signal booster 330 can perform the uplink AGC when the dynamic gain information satisfies an uplink AGC set point. The uplink AGC set point can be based on a length of the coaxial cable 350 (and corresponding coaxial cable loss) connecting the main signal booster 320 to the inline signal booster 330. The uplink AGC set point can correspond to a certain power level. When the uplink AGC set point is met at the inline signal booster 330 based on the dynamic gain information received from the main signal booster 320, the inline signal booster 330 can adjust its uplink AGC 332 to maintain network protection requirements. On the other hand, when the inline signal booster 330 receives dynamic gain information from the main signal booster 320 that does not satisfy the uplink AGC set point, the uplink AGC 332 in the inline signal booster 330 may not be adjusted.

In a more specific example, the inline signal booster 330 can access a lookup table to determine an uplink AGC value to be applied at the inline signal booster 330 based on the dynamic gain information received from the main signal booster 320. The lookup table can be stored in a data store of the signal booster system, and the lookup table can be accessible to the inline signal booster 330. The lookup table can include a plurality of uplink AGC values corresponding to a plurality of downlink/uplink RSSI values. Therefore, based on the dynamic gain information (which includes downlink/uplink RSSI values), the inline signal booster 330 can access the lookup table to identify an uplink AGC value corresponding to the dynamic gain information. After the uplink AGC value is identified from the lookup table, the inline signal booster 330 can apply the uplink AGC value, which can serve to meet a network protection standard. The uplink AGC value applied at the inline signal booster 330 can be different than an uplink AGC value applied at the main signal booster 320.

In one example, the main signal booster 320 can receive the downlink signal from the base station and the uplink signal from the inline signal booster 330, and the main signal booster 320 can determine the dynamic gain information based on the power level associated with the downlink signal and/or the power level associated with the uplink signal. The main signal booster 320 can access the lookup table to determine an uplink AGC value to be applied at the main signal booster 320 based on the dynamic gain information. In other words, both the main signal booster 320 and the inline signal booster 330 can access the lookup table to determine their respective uplink AGC values.

In one example, a system uplink gain of the signal booster system 300 can correspond to the uplink AGC 322 in the main signal booster 320 and the uplink AGC 332 in the inline signal booster 330. In other words, the system uplink gain can be equal to the uplink gain applied at the main signal booster 320 and the uplink gain applied at the inline signal booster 330. The system uplink gain of the signal booster system 300 can comply with a requirement of a regulatory body for a cellular consumer or commercial signal booster system. In addition, the main signal booster 320 can communicate the dynamic gain information to the inline signal booster 330 in accordance with a timing that complies with a requirement of the regulatory body for the cellular consumer or commercial signal booster system.

In one configuration, a default distribution of system gain for the signal booster system 300 (i.e., uplink AGC 322 at the main signal booster 320 versus uplink AGC 332 at the inline signal booster 330) can be determined during a field calibration. For example, the default distribution of system gain can depend on a coaxial cable length (and corresponding coaxial cable loss) connecting the main signal booster 320 to the inline signal booster 330. The coaxial cable loss can be measured for the inline signal booster 330 during the field calibration. The default distribution of system gain can be a baseline for the main signal booster 320 and the inline signal booster 330 under a low level signal input. The default distribution of system gain can be a static gain setting (as determined during the field calibration) for the main signal booster 320 and the inline signal booster 330 based on the coaxial cable loss. The default distribution of system gain can comply with overall system requirements set by the FCC.

After the field calibration, the signal booster system 300 can start operating in a normal mode. At this point, the distribution of system gain for the signal booster system 300 (i.e., uplink AGC 322 at the main signal booster 320 versus uplink AGC 332 at the inline signal booster 330) can be based on dynamic input signal factors, such as the dynamic gain information that includes the downlink RSSI information and the uplink RSSI information. As the dynamic gain information changes over a period of time, this dynamic distribution of system gain for the signal booster system 300 can be modified. For example, based on the dynamic gain information, the main signal booster 320 can adjust its uplink AGC 322 accordingly and the inline signal booster 330 can adjust its uplink AGC 332 accordingly. In other words, the dynamic distribution of system gain is now based on a dynamic gain setting. The main signal booster 320 and the inline signal booster 330 can work cooperatively to control an overall system uplink gain of the signal booster system 300.

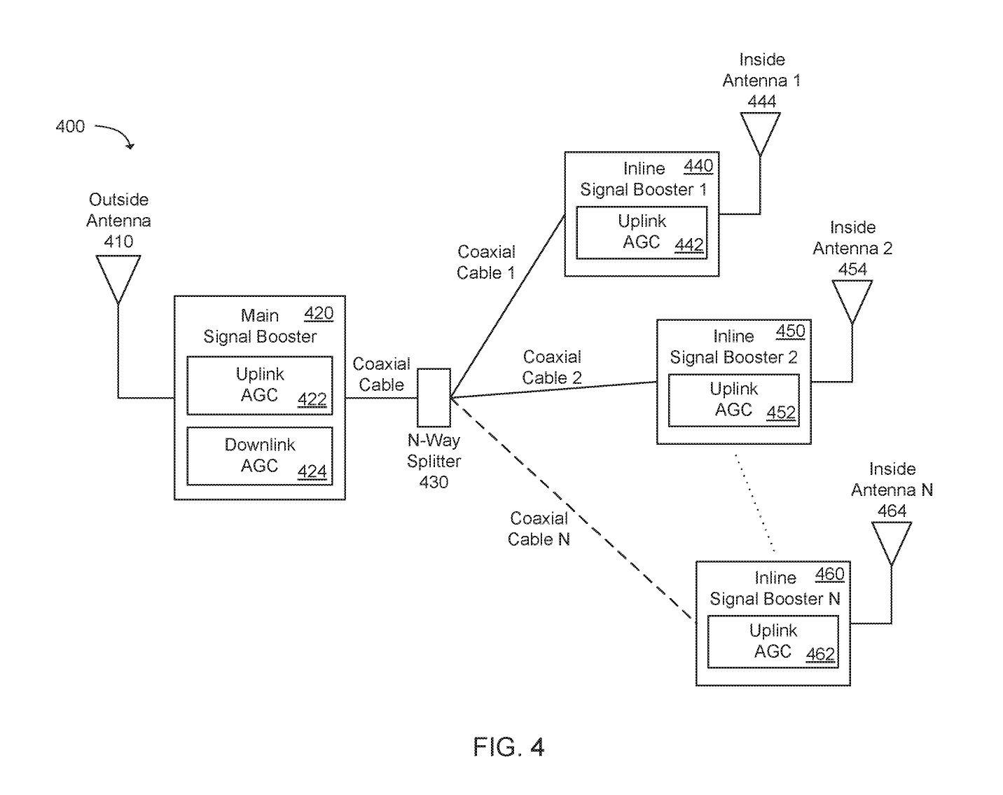

FIG. 4 illustrates an exemplary signal booster system 400 (or repeater system) that includes a main signal booster 420 (or main repeater) that is communicatively coupled to a plurality of inline signal boosters (or inline repeaters) in a parallel manner. The plurality of inline signal boosters can include a first inline signal booster 440, a second inline signal booster 450 and an Nth inline signal booster 460. The main signal booster 420 can be communicatively coupled to the plurality of inline signal boosters via an N-way splitter 430 and separate coaxial cables. Here, N can be an integer that corresponds to N inline signal boosters in the signal booster system 400. In this example, the main signal booster 420 can be communicatively coupled to the first inline signal booster 440 via a first coaxial cable, the main signal booster 420 can be communicatively coupled to the second inline signal booster 450 via a second coaxial cable, and the main signal booster 420 can be communicatively coupled to the Nth inline signal booster 460 via an Nth coaxial cable. The main signal booster 420 and the inline signal boosters 440, 450, 460 can both function to filter and amplify uplink and downlink signals. As described in further detail below, the main signal booster 420 and the inline signal boosters 440, 450, 460 can cooperate to dynamically control a system gain of the signal booster system 400 to meet varying environmental and input signal conditions.

In one example, the main signal booster 420 can be communicatively coupled to an outside antenna 410 (or donor antenna). In addition, the first inline signal booster 440 can be communicatively coupled to a first inside antenna 444 (or first server antenna), the second inline signal booster 450 can be communicatively coupled to a second inside antenna 454 (or second server antenna), and the Nth inline signal booster 460 can be communicatively coupled to an Nth inside antenna 464 (or Nth server antenna).

In one example, the main signal booster 420 can include an uplink automatic gain control (AGC) 422 and a downlink AGC 424. The uplink AGC 422 can function to control an uplink gain of an uplink signal path in the main signal booster 420, and the downlink AGC 424 can function to control a downlink gain of a downlink signal path in the main signal booster 420. In addition, the plurality of inline signal boosters can each include an uplink AGC, which can function to control an uplink gain of an uplink signal path of a respective inline signal booster. For example, the first inline signal booster 440 can include a first uplink AGC 442, the second inline signal booster 450 can include a second uplink AGC 452, and the Nth inline signal booster 460 can include an Nth uplink AGC 462.

In one example, the inline signal boosters 440, 450, 460 can each receive dynamic gain information from the main signal booster 420. The dynamic gain information can include downlink received signal strength indicator (RSSI) information and uplink RSSI information for the main signal booster 420. The inline signal boosters 440, 450, 460 can each access a shared lookup table to determine uplink AGC values to be applied at the respective inline signal boosters 440, 450, 460 based on the dynamic gain information received from the main signal booster 420. In other words, each of the inline signal boosters 440, 450, 460 can set their respective uplink AGC based on the dynamic gain information received from the main signal booster 420.

In one example, uplink AGC values applied to the first inline signal booster 440 can be different than uplink AGC values applied to the second inline signal booster 450 based on different coaxial cable losses associated with the first coaxial cable and the second coaxial cable. In other words, since the first inline signal booster 440 and the second inline signal booster 450 can have different coaxial cable losses, the uplink AGC values applied at the first inline signal booster 440 and the second inline signal booster 450 can be adjusted appropriately to account for the different coaxial cable losses.

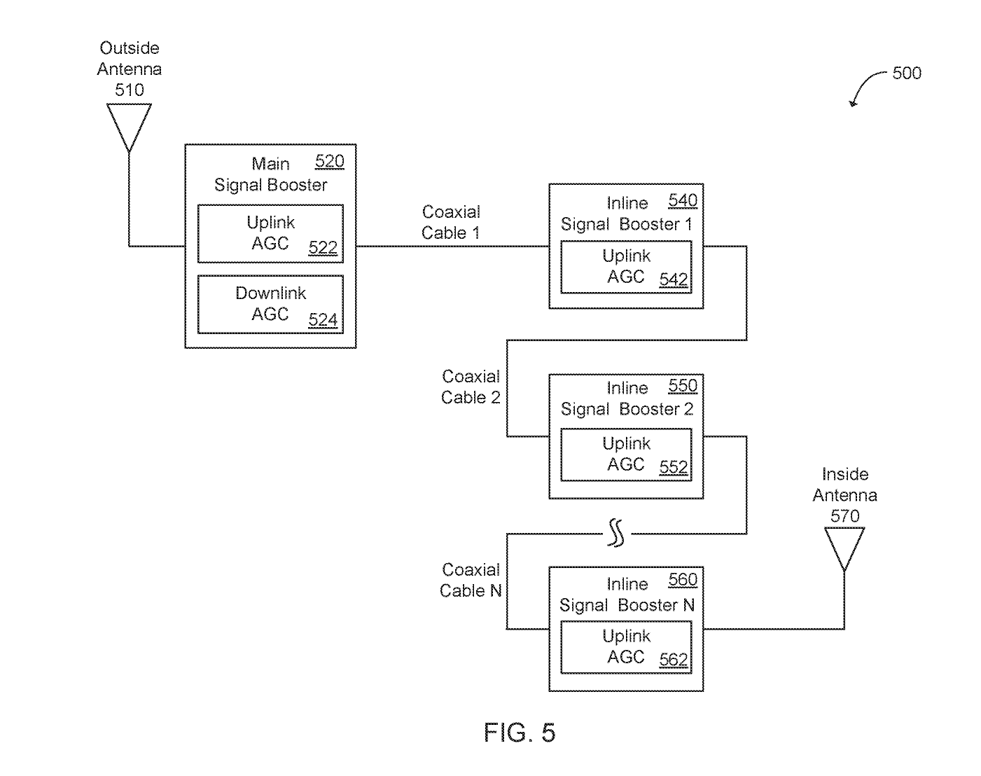

FIG. 5 illustrates an exemplary signal booster system 500 (or repeater system) that includes a main signal booster 520 (or main repeater) that is communicatively coupled to a plurality of inline signal boosters (or inline repeaters) in a serial manner. The plurality of inline signal boosters can include a first inline signal booster 540 with a first uplink automatic gain control (AGC) 542, a second inline signal booster 550 with a second uplink AGC 552 and an Nth inline signal booster 560 with an Nth uplink AGC 562. Here, N can be an integer that corresponds to N inline signal boosters in the signal booster system 500. The main signal booster 520 can be communicatively coupled to the plurality of inline signal boosters via separate coaxial cables. For example, the main signal booster 520 can be communicatively coupled to the first inline signal booster 540 via a first coaxial cable, the first inline signal booster 540 can be communicatively coupled to the second inline signal booster 550 via a second coaxial cable, and the second inline signal booster 550 can be communicatively coupled to the Nth inline signal booster 560 via an Nth coaxial cable. The main signal booster 520 can include an uplink AGC 522 and a downlink AGC 524. In addition, the main signal booster 520 can be communicatively coupled to an outside antenna 510 (or donor antenna), and the Nth inline signal booster 560 can be communicatively coupled to an inside antenna 570 (or server antenna).

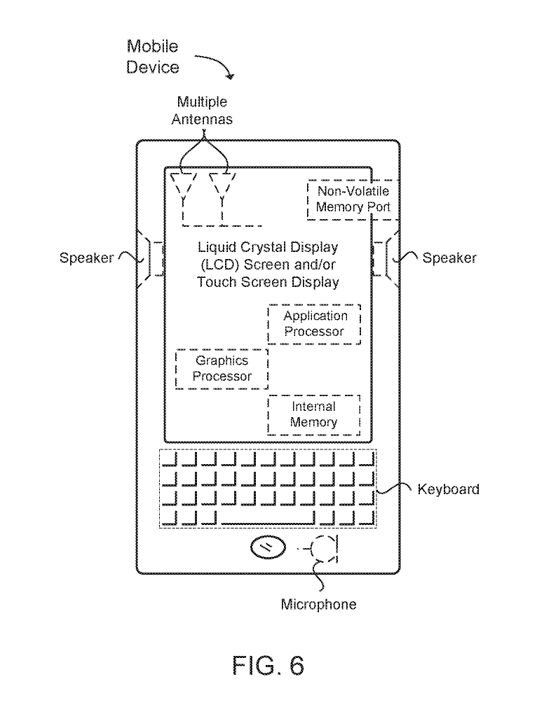

FIG. 6 provides an example illustration of the wireless device, such as a user equipment (UE), a mobile station (MS), a mobile communication device, a tablet, a handset, a wireless transceiver coupled to a processor, or other type of wireless device. The wireless device can include one or more antennas configured to communicate with a node or transmission station, such as an access point (AP), a base station (BS), an evolved Node B (eNB), a baseband unit (BBU), a remote radio head (RRH), a remote radio equipment (RRE), a relay station (RS), a radio equipment (RE), a remote radio unit (RRU), a central processing module (CPM), or other type of wireless wide area network (WWAN) access point. The wireless device can communicate using separate antennas for each wireless communication standard or shared antennas for multiple wireless communication standards. The wireless device can communicate in a wireless local area network (WLAN), a wireless personal area network (WPAN), and/or a WWAN.

FIG. 6 also provides an illustration of a microphone and one or more speakers that can be used for audio input and output from the wireless device. The display screen can be a liquid crystal display (LCD) screen, or other type of display screen such as an organic light emitting diode (OLED) display. The display screen can be configured as a touch screen. The touch screen can use capacitive, resistive, or another type of touch screen technology. An application processor and a graphics processor can be coupled to internal memory to provide processing and display capabilities. A non-volatile memory port can also be used to provide data input/output options to a user. The non-volatile memory port can also be used to expand the memory capabilities of the wireless device. A keyboard can be with the wireless device or wirelessly connected to the wireless device to provide additional user input. A virtual keyboard can also be provided using the touch screen.

### EXAMPLES

The following examples pertain to specific technology embodiments and point out specific features, elements, or actions that can be used or otherwise combined in achieving such embodiments.

Example 1 includes a repeater system, comprising: a main repeater, comprising: an amplifier for an uplink signal path; an uplink automatic gain control (AGC) associated with the amplifier for the uplink signal path of the main repeater; and a controller configured to communicate dynamic gain information; and an inline repeater communicatively coupled to the main repeater via a coaxial cable, the inline repeater comprising: an amplifier for an uplink signal path; an uplink AGC associated with the amplifier for the uplink signal path of the inline repeater; and a controller configured to receive the dynamic gain information from the main repeater and set the uplink AGC of the inline repeater based on the dynamic gain information.

Example 2 includes the repeater system of Example 1, wherein the controller in the inline repeater is configured to access a lookup table to determine an uplink AGC value to be applied at the inline repeater based on the dynamic gain information received from the main repeater.

Example 3 includes the repeater system of any of Examples 1 to 2, wherein the controller in the main repeater is configured to access a lookup table to determine an uplink AGC value to be applied at the main repeater based on the dynamic gain information.

Example 4 includes the repeater system of any of Examples 1 to 3, wherein the controller in the inline repeater is configured to apply a static gain setting based on a measured coaxial cable loss of the coaxial cable that communicatively couples the main repeater and the inline repeater.

Example 5 includes the repeater system of any of Examples 1 to 4, wherein the controller in the inline repeater is configured to apply a dynamic uplink AGC setting based on the dynamic gain information received from the main repeater.

Example 6 includes the repeater system of any of Examples 1 to 5, wherein the controller in the main repeater is configured to apply a dynamic uplink AGC setting based on the dynamic gain information.

Example 7 includes the repeater system of any of Examples 1 to 6, wherein the dynamic gain information includes downlink received signal strength indicator (RSSI) information and uplink RSSI information for the main repeater.

Example 8 includes the repeater system of any of Examples 1 to 7, wherein the main repeater is configured to: receive a downlink signal from a base station; receive an uplink signal from the inline repeater; and determine the dynamic gain information based on a power level associated with the downlink signal and a power level associated with the uplink signal.

Example 9 includes the repeater system of any of Examples 1 to 8, wherein a system uplink gain of the repeater system complies with a requirement of a regulatory body for a cellular consumer signal booster system, wherein the system uplink gain corresponds to the uplink AGC in the main repeater and the uplink AGC in the inline repeater.

Example 10 includes the repeater system of any of Examples 1 to 9, wherein a timing of communications between the main repeater and the inline repeater complies with a requirement of a regulatory body for a cellular consumer signal booster system.

Example 11 includes the repeater system of any of Examples 1 to 10, wherein a distribution of system gain between the main repeater and the inline repeater in the repeater system is based on a measured coaxial cable loss of the coaxial cable that communicatively couples the main repeater and the inline repeater.

Example 12 includes the repeater system of any of Examples 1 to 11, wherein the main repeater further comprises: an amplifier for a downlink signal path; and a downlink AGC associated with the amplifier for the downlink signal path of the main repeater.

Example 13 includes the repeater system of any of Examples 1 to 12, wherein the main repeater and the inline repeater are configured to each perform uplink AGC to maintain network protection standards.

Example 14 includes the repeater system of any of Examples 1 to 13, further comprising: an outside antenna communicatively coupled to the main repeater; and an inside antenna communicatively coupled to the inline repeater.

Example 15 includes the repeater system of any of Examples 1 to 14, wherein the inline repeater is configured to determine to set the uplink AGC when the dynamic gain information satisfies an uplink AGC set point.

Example 16 includes a signal booster system, comprising: a main signal booster; and a plurality of inline signal boosters communicatively coupled to the main signal booster via separate coaxial cables, wherein each inline signal booster in the plurality of inline signal boosters is configured to set its uplink automatic gain control (AGC) based on dynamic gain information received from the main signal booster.

Example 17 includes the signal booster system of Example 16, wherein the inline signal booster is configured to: receive, at a controller, downlink received signal strength indicator (RSSI) information for the main signal booster; receive, at the controller, uplink RSSI information from an inside antenna communicatively coupled to the inline signal booster; and access, at the controller, a lookup table to determine an uplink AGC value to be applied at the inline signal booster based on the dynamic gain information which includes the downlink RSSI information and the uplink RSSI information.

Example 18 includes the signal booster system of any of Examples 16 to 17, wherein a first inline signal booster in the plurality of inline signal boosters is communicatively coupled to the main signal booster via a first coaxial cable and a second inline signal booster in the plurality of inline signal boosters is communicatively coupled to the main signal booster via a second coaxial cable, wherein an uplink AGC value applied to the first inline signal booster is different than an uplink AGC value applied to the second inline signal booster based on different coaxial cable losses associated with the first coaxial cable and the second coaxial cable.

Example 19 includes the signal booster system of any of Examples 16 to 18, wherein the plurality of inline signal boosters are communicatively coupled to the main signal booster via a splitter.

Example 20 includes the signal booster system of any of Examples 16 to 19, wherein the plurality of inline signal boosters are communicatively coupled to individual inside antennas.

Example 21 includes a main signal booster in a signal booster system, the main signal booster comprising a controller configured to: receive a downlink signal from a base station; receive an uplink signal from an inline signal booster in the signal booster system; determine dynamic gain information based on a power level associated with the downlink signal and a power level associated with the uplink signal; perform uplink automatic gain control (AGC) at the main signal booster; and send the dynamic gain information to the inline signal booster in the signal booster system to enable the inline signal booster to perform uplink AGC using the dynamic gain information.

Example 22 includes the main signal booster of Example 21, wherein the controller is configured to perform downlink AGC.

Example 23 includes the main signal booster of any of Examples 21 to 22, wherein the dynamic gain information includes downlink received signal strength indicator (RSSI) information and uplink RSSI information.

Example 24 includes the main signal booster of any of Examples 21 to 23, wherein the main signal booster is communicatively coupled to the inline signal booster via a coaxial cable.

Example 25 includes an inline signal booster in a signal booster system, the inline signal booster comprising a controller configured to: receive dynamic gain information from a main signal booster in the signal booster system; determine an uplink automatic gain control (AGC) value based on the dynamic gain information received from the main signal booster; and apply the uplink AGC value to the inline signal booster.

Example 26 includes the inline signal booster of Example 25, wherein the controller is further configured to access a lookup table to determine the uplink AGC value to be applied at the inline signal booster based on the dynamic gain information.

Example 27 includes the inline signal booster of any of Examples 25 to 26, wherein the controller is further configured to access a lookup table to determine the uplink AGC value to be applied at the inline signal booster based on the dynamic gain information and attenuation due to signal losses between the main signal booster and the inline signal booster.

Example 28 includes the inline signal booster of any of Examples 25 to 27, wherein the inline signal booster is communicatively coupled to the main signal booster via a coaxial cable.

Example 29 includes the inline signal booster of any of Examples 25 to 28, wherein the controller is configured to apply a static gain setting based on a measured coaxial cable loss of a coaxial cable that communicatively couples the main signal booster and the inline signal booster.

Example 30 includes the inline signal booster of any of Examples 25 to 29, wherein the controller is configured to apply a dynamic uplink AGC setting based on the dynamic gain information received from the main signal booster.

Various techniques, or certain aspects or portions thereof, can take the form of program code (i.e., instructions) embodied in tangible media, such as floppy diskettes, compact disc-read-only memory (CD-ROMs), hard drives, non-transitory computer readable storage medium, or any other machine-readable storage medium wherein, when the program code is loaded into and executed by a machine, such as a computer, the machine becomes an apparatus for practicing the various techniques. Circuitry can include hardware, firmware, program code, executable code, computer instructions, and/or software. A non-transitory computer readable storage medium can be a computer readable storage medium that does not include signal. In the case of program code execution on programmable computers, the computing device can include a processor, a storage medium readable by the processor (including volatile and non-volatile memory and/or storage elements), at least one input device, and at least one output device. The volatile and non-volatile memory and/or storage elements can be a random-access memory (RAM), erasable programmable read only memory (EPROM), flash drive, optical drive, magnetic hard drive, solid state drive, or other medium for storing electronic data. One or more programs that can implement or utilize the various techniques described herein can use an application programming interface (API), reusable controls, and the like. Such programs can be implemented in a high level procedural or object oriented programming language to communicate with a computer system. However, the program(s) can be implemented in assembly or machine language, if desired. In any case, the language can be a compiled or interpreted language, and combined with hardware implementations.

As used herein, the term processor can include general purpose processors, specialized processors such as VLSI, FPGAs, or other types of specialized processors, as well as base band processors used in transceivers to send, receive, and process wireless communications.

It should be understood that many of the functional units described in this specification have been labeled as modules, in order to more particularly emphasize their implementation independence. For example, a module can be implemented as a hardware circuit comprising custom very-large-scale integration (VLSI) circuits or gate arrays, off-the-shelf semiconductors such as logic chips, transistors, or other discrete components. A module can also be implemented in programmable hardware devices such as field programmable gate arrays, programmable array logic, programmable logic devices or the like.

In one example, multiple hardware circuits or multiple processors can be used to implement the functional units described in this specification. For example, a first hardware circuit or a first processor can be used to perform processing operations and a second hardware circuit or a second processor (e.g., a transceiver or a baseband processor) can be used to communicate with other entities. The first hardware circuit and the second hardware circuit can be incorporated into a single hardware circuit, or alternatively, the first hardware circuit and the second hardware circuit can be separate hardware circuits.

Modules can also be implemented in software for execution by various types of processors. An identified module of executable code can, for instance, comprise one or more physical or logical blocks of computer instructions, which can, for instance, be organized as an object, procedure, or function. Nevertheless, the executables of an identified module need not be physically located together, but can comprise disparate instructions stored in different locations which, when joined logically together, comprise the module and achieve the stated purpose for the module.

Indeed, a module of executable code can be a single instruction, or many instructions, and can even be distributed over several different code segments, among different programs, and across several memory devices. Similarly, operational data can be identified and illustrated herein within modules, and can be embodied in any suitable form and organized within any suitable type of data structure. The operational data can be collected as a single data set, or can be distributed over different locations including over different storage devices, and can exist, at least partially, merely as electronic signals on a system or network. The modules can be passive or active, including agents operable to perform desired functions.

Reference throughout this specification to “an example” or “exemplary” means that a particular feature, structure, or characteristic described in connection with the example is included in at least one embodiment of the present invention. Thus, appearances of the phrases “in an example” or the word “exemplary” in various places throughout this specification are not necessarily all referring to the same embodiment.

As used herein, a plurality of items, structural elements, compositional elements, and/or materials can be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary. In addition, various embodiments and example of the present invention can be referred to herein along with alternatives for the various components thereof. It is understood that such embodiments, examples, and alternatives are not to be construed as defacto equivalents of one another, but are to be considered as separate and autonomous representations of the present invention.

Furthermore, the described features, structures, or characteristics can be combined in any suitable manner in one or more embodiments. In the following description, numerous specific details are provided, such as examples of layouts, distances, network examples, etc., to provide a thorough understanding of embodiments of the invention. One skilled in the relevant art will recognize, however, that the invention can be practiced without one or more of the specific details, or with other methods, components, layouts, etc. In other instances, well-known structures, materials, or operations are not shown or described in detail to avoid obscuring aspects of the invention.

While the forgoing examples are illustrative of the principles of the present invention in one or more particular applications, it will be apparent to those of ordinary skill in the art that numerous modifications in form, usage and details of implementation can be made without the exercise of inventive faculty, and without departing from the principles and concepts of the invention. Accordingly, it is not intended that the invention be limited, except as by the claims set forth below.

What is claimed is:

1. A repeater system, comprising:
a main repeater, comprising:
an amplifier for an uplink signal path;
an uplink automatic gain control (AGC) associated with the amplifier for the uplink signal path of the main repeater; and
a controller configured to communicate dynamic gain information; and
an inline repeater communicatively coupled to the main repeater via a coaxial cable, the inline repeater comprising:
an amplifier for an uplink signal path;
an uplink AGC associated with the amplifier for the uplink signal path of the inline repeater; and
a controller configured to receive the dynamic gain information from the main repeater and set the uplink AGC of the inline repeater based on the dynamic gain information.

2. The repeater system of claim 1, wherein the controller in the inline repeater is configured to access a lookup table to determine an uplink AGC value to be applied at the inline repeater based on the dynamic gain information received from the main repeater.

3. The repeater system of claim 1, wherein the controller in the main repeater is configured to access a lookup table to determine an uplink AGC value to be applied at the main repeater based on the dynamic gain information.

4. The repeater system of claim 1, wherein the controller in the inline repeater is configured to apply a static gain setting based on a measured coaxial cable loss of the coaxial cable that communicatively couples the main repeater and the inline repeater.

5. The repeater system of claim 1, wherein the controller in the inline repeater is configured to apply a dynamic uplink AGC setting based on the dynamic gain information received from the main repeater.

6. The repeater system of claim 1, wherein the controller in the main repeater is configured to apply a dynamic uplink AGC setting based on the dynamic gain information.

7. The repeater system of claim 1, wherein the dynamic gain information includes downlink received signal strength indicator (RSSI) information and uplink RSSI information for the main repeater.

8. The repeater system of claim 1, wherein the main repeater is configured to:
receive a downlink signal from a base station;
receive an uplink signal from the inline repeater; and
determine the dynamic gain information based on a power level associated with the downlink signal and a power level associated with the uplink signal.

9. The repeater system of claim 1, wherein a system uplink gain of the repeater system complies with a requirement of a regulatory body for a cellular consumer signal booster system, wherein the system uplink gain corresponds to the uplink AGC in the main repeater and the uplink AGC in the inline repeater.

10. The repeater system of claim 1, wherein a timing of communications between the main repeater and the inline repeater complies with a requirement of a regulatory body for a cellular consumer signal booster system.

11. The repeater system of claim 1, wherein a distribution of system gain between the main repeater and the inline repeater in the repeater system is based on a measured coaxial cable loss of the coaxial cable that communicatively couples the main repeater and the inline repeater.

12. The repeater system of claim 1, wherein the main repeater further comprises:
an amplifier for a downlink signal path; and
a downlink AGC associated with the amplifier for the downlink signal path of the main repeater.

13. The repeater system of claim 1, wherein the main repeater and the inline repeater are configured to each perform uplink AGC to maintain network protection standards.

14. The repeater system of claim 1, further comprising:
an outside antenna communicatively coupled to the main repeater; and
an inside antenna communicatively coupled to the inline repeater.

15. The repeater system of claim 1, wherein the inline repeater is configured to determine to set the uplink AGC when the dynamic gain information satisfies an uplink AGC set point.

16. A signal booster system, comprising:
a main signal booster; and
a plurality of inline signal boosters communicatively coupled to the main signal booster via separate coaxial cables, wherein each inline signal booster in the plurality of inline signal boosters is configured to set its uplink automatic gain control (AGC) based on dynamic gain information received from the main signal booster.

17. The signal booster system of claim 16, wherein the inline signal booster is configured to:
receive, at a controller, downlink received signal strength indicator (RSSI) information for the main signal booster;
receive, at the controller, uplink RSSI information from an inside antenna communicatively coupled to the inline signal booster; and
access, at the controller, a lookup table to determine an uplink AGC value to be applied at the inline signal booster based on the dynamic gain information which includes the downlink RSSI information and the uplink RSSI information.

18. The signal booster system of claim 16, wherein a first inline signal booster in the plurality of inline signal boosters is communicatively coupled to the main signal booster via a first coaxial cable and a second inline signal booster in the plurality of inline signal boosters is communicatively coupled to the main signal booster via a second coaxial cable, wherein an uplink AGC value applied to the first inline signal booster is different than an uplink AGC value applied to the second inline signal booster based on different coaxial cable losses associated with the first coaxial cable and the second coaxial cable.

19. The signal booster system of claim 16, wherein the plurality of inline signal boosters are communicatively coupled to the main signal booster via a splitter.

20. The signal booster system of claim 16, wherein the plurality of inline signal boosters are communicatively coupled to individual inside antennas.

21. A main signal booster in a signal booster system, the main signal booster comprising a controller configured to:
receive a downlink signal from a base station;
receive an uplink signal from an inline signal booster in the signal booster system;
determine dynamic gain information based on a power level associated with the downlink signal and a power level associated with the uplink signal;
perform uplink automatic gain control (AGC) at the main signal booster; and
send the dynamic gain information to the inline signal booster in the signal booster system to enable the inline signal booster to perform uplink AGC using the dynamic gain information.

22. The main signal booster of claim 21, wherein the controller is configured to perform downlink AGC.

23. The main signal booster of claim 21, wherein the dynamic gain information includes downlink received signal strength indicator (RSSI) information and uplink RSSI information.

24. The main signal booster of claim 21, wherein the main signal booster is communicatively coupled to the inline signal booster via a coaxial cable.

25. An inline signal booster in a signal booster system, the inline signal booster comprising a controller configured to:
receive dynamic gain information from a main signal booster in the signal booster system;
determine an uplink automatic gain control (AGC) value based on the dynamic gain information received from the main signal booster; and
apply the uplink AGC value to the inline signal booster.

26. The inline signal booster of claim 25, wherein the controller is further configured to access a lookup table to determine the uplink AGC value to be applied at the inline signal booster based on the dynamic gain information.

27. The inline signal booster of claim 25, wherein the controller is further configured to access a lookup table to determine the uplink AGC value to be applied at the inline signal booster based on the dynamic gain information and attenuation due to signal losses between the main signal booster and the inline signal booster.

28. The inline signal booster of claim 25, wherein the inline signal booster is communicatively coupled to the main signal booster via a coaxial cable.

29. The inline signal booster of claim 25, wherein the controller is configured to apply a static gain setting based on a measured coaxial cable loss of a coaxial cable that communicatively couples the main signal booster and the inline signal booster.

30. The inline signal booster of claim 25, wherein the controller is configured to apply a dynamic uplink AGC setting based on the dynamic gain information received from the main signal booster.
